(19) United States
(12) Patent Application Publication
(10) Pub. No.: US 2010/0085388 A1
(43) Pub. Date: Apr. 8, 2010

(54) ACTIVE MATRIX DISPLAY DEVICE

(76) Inventor: Kazuyoshi Kawabe, Kanagawa (JP)

Correspondence Address: EASTMAN KODAK COMPANY;PATENT LEGAL STAFF, 343 STATE STREET, ROCHESTER, NY, 14650-2201, US

(21) Appl. No.: 12/522,397

(22) PCT Filed: Jan. 8, 2008
(86) PCT No.: PCT/US08/00267

§ 371 Date: Jul. 8, 2009

(30) Foreign Application Priority Data
Jan. 23, 2007 (JP) 2007-012895

(51) Int. Cl. G09G 3/30; G09G 5/10

(52) U.S. Cl. 345/690; 345/77

(57) ABSTRACT

An active matrix display device, wherein each pixel includes a plurality of selectable divided pixels, wherein each divided pixel has a 1-bit static data storage element and emits light based on supplied data; and the plurality of divided pixels each produces a weighted amount of light so that the selected divided pixels will cause a predetermined amount of light to be produced.

### CROSS-REFERENCE TO RELATED APPLICATION

This application claims priority of Japanese Patent Application No. 2007-012895 filed Jan. 23, 2007, which is incorporated herein by reference in its entirety.

### FIELD OF THE INVENTION

The present invention relates to an active matrix display device in which a pixel includes a plurality of divided pixels.

### BACKGROUND OF THE INVENTION

Display panels having an organic electroluminescence (hereinafter simply referred to as “1L”) element as a light-emitting element are known, and are becoming more widely available as thin display devices. EL display devices are classified into passive organic EL display devices and active (active matrix) EL display devices. Of these, the active matrix EL display devices are becoming more popular, in view that higher resolution is achieved by an active matrix EL display device in which a thin film transistor is provided in each pixel and display is controlled.

An organic EL element is a current-driven element. In order to control the amount of light emission with analog data, a driving transistor in which the amount of current is controlled according to a data voltage is provided in each pixel. However, difficulty is encountered in inhibiting variation in characteristics of the driving transistors, and allowing an appropriate current to always flow through the driving transistor according to the data voltage.

For this purpose, there has been proposed a method in which the active matrix organic EL panel is driven digitally (see WO 2005-116971). With digital driving, the amount of light emission at each pixel may be maintained constant, and the influences of the characteristic variation of driving transistors can be inhibited.

In digital driving, one frame period is divided into a plurality of sub-frame periods, and whether or not light is emitted during a sub-frame period having a certain light emission period is controlled. Therefore, the data must be written to the pixel for each sub-frame. Because of this, a frame memory must be provided in order to allow data of one frame to be written in the frame memory and data corresponding to each sub-frame to be read from the frame memory and supplied to each pixel.

### SUMMARY OF THE INVENTION

According to one aspect of the present invention, there is provided an active matrix display device wherein each pixel includes a plurality of divided pixels, wherein each divided pixel has a data storage element and emits light based on supplied data, and amounts of light emission by the divided pixels are weighted, and each bit of data of a plurality of bits for a pixel is supplied to the corresponding divided pixel in which the amount of light emission is correspondingly weighted.

According to another aspect of the present invention, preferably, in the active matrix display device, the amounts of light emission of the divided pixels are weighted by weighting power supply voltages to be supplied to the respective divided pixels.

According to another aspect of the present invention, preferably, in the active matrix display device, the power supply voltage to be supplied to each divided pixel can be switched.

According to another aspect of the present invention, preferably, in the active matrix display device, each of the divided pixels includes a 1-bit static memory as the data storage element.

According to another aspect of the present invention, preferably, in the active matrix display device, each of the divided pixels includes an organic electroluminescence element as a light-emitting element.

According to various aspects of the present invention, by dividing a pixel into a plurality of divided pixels and setting light emission intensities to differ among the divided pixels, the light emission of the divided pixels can be controlled with grayscale data and a grayscale display can be achieved. Therefore, the frame memory is no longer necessary.

### BRIEF DESCRIPTION OF THE DRAWINGS

Preferred embodiments of the present invention will be described in detail by reference to the drawings, wherein:

FIG. 1A is an equivalent circuit diagram of a divided pixel;

FIG. 1B is a diagram showing placement and connection of the divided pixel;

FIG. 2A is an equivalent circuit diagram of a pixel;

FIG. 2B is a diagram showing placement and connection of the pixel;

FIG. 3 is a diagram showing a current-voltage characteristic of an organic EL element;

FIG. 4 is an overall structural diagram of an organic EL panel;

FIG. 5 is a driving timing chart of the organic EL panel;

FIG. 6 is a table showing switching of a power supply voltage setting; and

FIG. 7 is an overall structural diagram of an organic EL panel including only P-type transistors.

### DESCRIPTION OF THE PREFERRED EMBODIMENT

A preferred embodiment of the present invention will now be described by reference to the drawings.

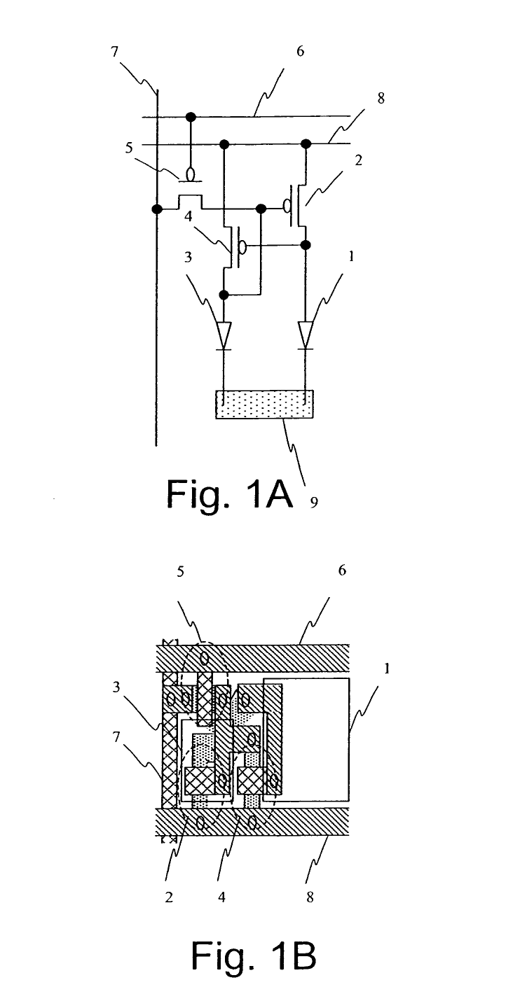

FIGS. 1A and 1B show a structure of a divided pixel circuit in which a static memory is introduced in a pixel circuit. FIG. 1A is an equivalent circuit diagram of the divided pixel or the like, and FIG. 1B is a diagram showing placement and connection of the divided pixel circuit as viewed from a side opposite the light emission surface.

A pixel in FIGS. 1A and 1B include a first organic electroluminescence (“EL”) element 1 which contributes to light emission, a first driving transistor 2 which drives the first organic EL element 1, a second organic EL element 3 which does not contribute to light emission, a second driving transistor 4 which drives the second organic EL element 3, and a gate transistor 5 which controls supply. A gate line 6 to which a selection signal is supplied to the gate electrode of gate transistor 5. Data voltages are supplied on a data line 7 to a gate terminal of the first driving transistor 2. In this example configuration, the first driving transistor 2, the second driving transistor 4, and the gate transistor 5 are p-channel transistors.

An anode of the first organic EL element 1 is connected to a drain terminal of the first driving transistor 2 and to a gate terminal of the second driving transistor 4. A gate terminal of the first driving transistor 2 is connected to an anode of the second organic EL element 3, to a drain terminal of the second driving transistor 4, and to a source terminal of the gate transistor 5. A gate terminal of the gate transistor 5 is connected to the gate line 6, and the drain terminal of the gate transistor 5 is connected to the data line 7. Source terminals of the first driving transistor 2 and the second driving transistor 4 are connected to a power supply line 8, and cathodes of the first organic EL element 1 and the second organic EL element 3 are connected to a cathode electrode 9.

In a pixel having such a structure, when the gate line 6 is selected (when the gate line 6 is set at a Low level), the gate transistor 5 is switched ON, and a data voltage supplied on the data line is read into the pixel circuit through the gate transistor 5. When the data voltage is Low, the first driving transistor 2 is switched ON. When the first driving transistor 2 is switched ON, the anode of the first organic EL element 1 is connected to the power supply line 8 on which a power supply voltage VDD is supplied, a current flows through the first organic EL element 1, and light is emitted. At the same time, the gate terminal of the second driving transistor 4 is also set at VDD, the second driving transistor 4 is switched OFF, and a potential of the anode of the second organic EL element 3 is dropped to a cathode potential VSS. Because the cathode potential VSS is supplied to the gate terminal of the first driving transistor 2, the written data Low continue to be maintained while VDD and VSS are being supplied, even after the gate line 6 is set to High and the gate transistor 5 is switched OFF.

When the data voltage is High, the first driving transistor 2 is switched OFF and the potential of the anode of the first organic EL element 1 is dropped to the cathode potential VSS. Because the cathode potential VSS is supplied to the gate terminal of the second driving transistor 4, the second driving transistor 4 is switched ON, the anode of the second organic EL element 3 is connected to the power supply line 8 on which the power supply voltage VDD is supplied, and current flows through the second organic EL element 3. The anode potential of the second organic EL element 3 is reflected in the gate terminal of the first driving transistor 2, and the gate terminal of the first driving transistor 2 is set to the power supply voltage VDD. Thus, even after the gate line 6 is set to High and the gate transistor 5 is switched OFF, the written data High is maintained while VDD and VSS are being supplied.

As described, in the pixel of FIGS. 1A and 1B, data are stored in a static memory including the first driving transistor 2 and the second driving transistor 4, and light emission from the first organic EL element 1 is controlled with the static memory. Therefore, because the data are maintained after once having been written, a refresh operation to periodically rewrite data at a predetermined period is not necessary. In the pixel of FIGS. 1A and 1B, because the second organic EL element 3 does not contribute to light emission, the light emission state of the pixel is determined by the light emission state of the first organic EL element 1.

As a method of forming the second organic EL element 3 which does not contribute to light emission, there is a method of forming an element which does not emit light and which differs from the first organic EL element 1. In this method, however, because two elements including the first organic EL element 1 which emits light and the organic EL element 3 which does not emit light must be formed, the manufacturing process becomes complicated. Alternatively, the second organic EL element 3 can be easily formed by forming the first and second organic EL elements as elements of the same structure and blocking light with a line forming a part of the pixel circuit or with a black matrix so that the light is not emitted to the outside from the light emission surface.

In either case, because the second organic EL element 3 does not contribute to light emission, it is preferable to place and connect the second organic EL element 3 with a small area so that a large light emission area can be secured for the first organic EL element 1 which emits light, as shown in FIG. 1B.

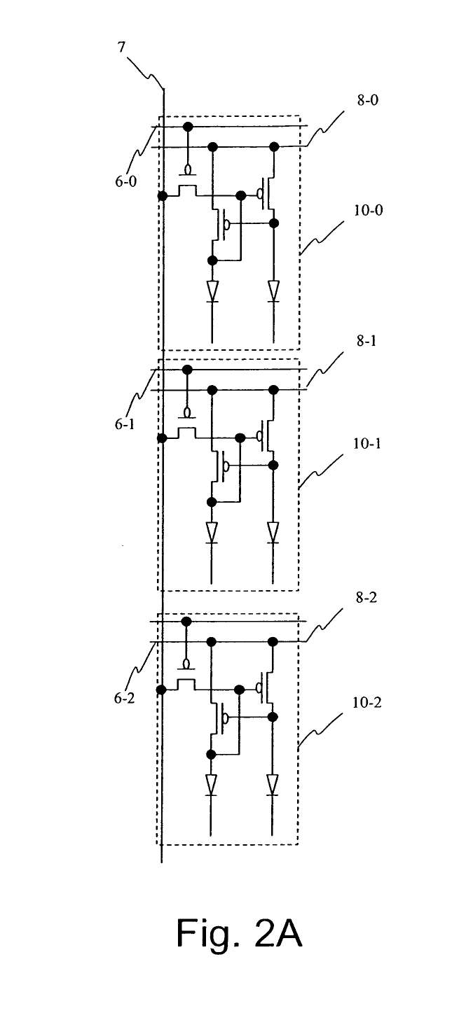

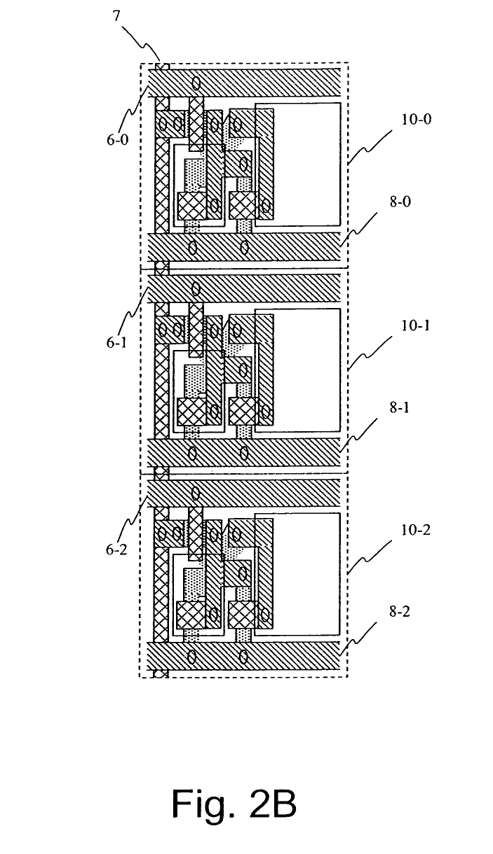

FIGS. 2A and 2B show an example structure in which a pixel for one color includes three divided pixels 10-0, 10-1, and 10-2. More specifically, the divided pixels 10-0, 10-1, and 10-2 are pixels of the colors, and each of pixels of, for example, R (red), G (green), B (blue), and W (white) includes three divided pixels as shown in FIGS. 2A and 2B. FIG. 2A is an equivalent circuit diagram, and FIG. 2B is a diagram of placement and connection as viewed from a side opposite the light emission surface.

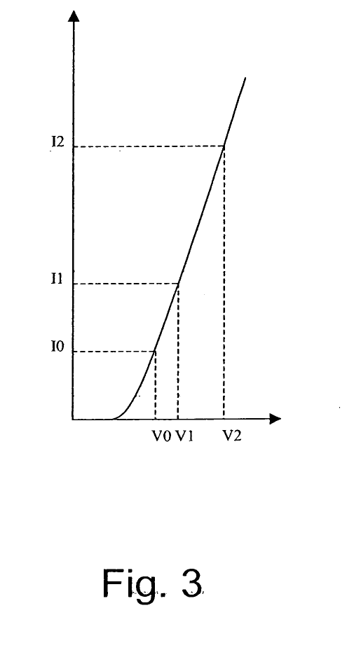

In the three divided pixels 10-0, 10-1, and 10-2 in the drawings, power supply lines 8-0, 8-1, and 8-2 are placed, and power supply voltages V0, V1, and V2 are supplied to the power supply lines 8-0, 8-1, and 8-2, which are determined by a current-voltage characteristic diagram of the organic EL element shown in FIG. 3.

As shown in FIG. 3, the power supply voltages V0, V1, and V2 are voltages which are determined such that a ratio among currents I0, I1, and I2 to be supplied through the organic EL elements of the divided pixels 10-0, 10-1, and 10-2, respectively, is 1:2:4. When the organic EL elements are switched ON by data voltages supplied to the divided pixels 10-0, 10-1, and 10-2, 8 different light emission intensities can be obtained. For example, when gate line 6-0 is sequentially selected and Low data are written in the divided pixel 10-0, the gate line 6-1 is then selected and High data are written to the divided pixel 10-1, and the gate line 6-2 is then selected and Low data are written to the divided pixel 10-2, the divided pixel 10-0 is switched ON, the divided pixel 10-1 is switched OFF, and the divided pixel 10-2 is switched ON. Thus, a pixel current of I=I0+I2=1*I0+4*I0=5*I0 is created. Because the light emission intensity is proportional to the current, a brightness which is 5/7 of the beak brightness in which all divided pixels emit light is created.

In this case, because different power supply voltages V0, V1, and V2 are supplied to the divided pixels 10-0, 10-1, and 10-2, the data voltages to be written to the divided pixels 10-0, 10-1, and 10-2 must be voltages which can switch the first driving transistors 2 of the divided pixels 10-0, 10-1, and 10-20N and OFF. Because voltage V2 is the maximum power supply voltage in this example configuration, by setting, for example, the ON voltage to VSS and the OFF voltage to V2, it is possible to switch all of the divided pixels ON and OFF by the data voltage.

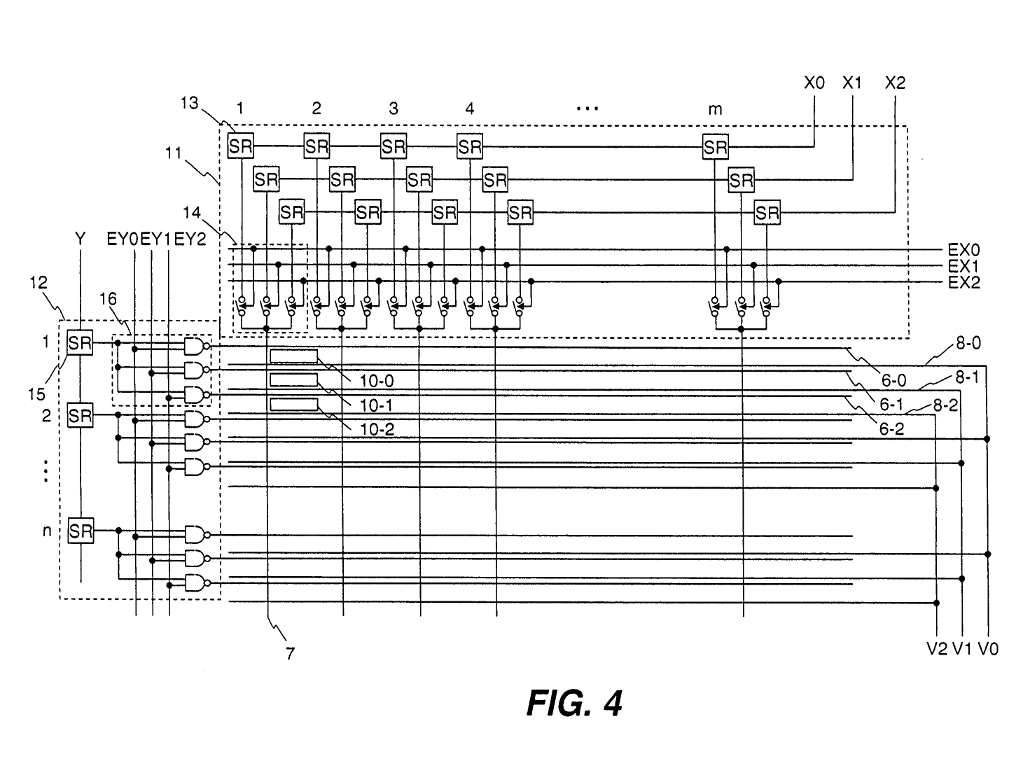

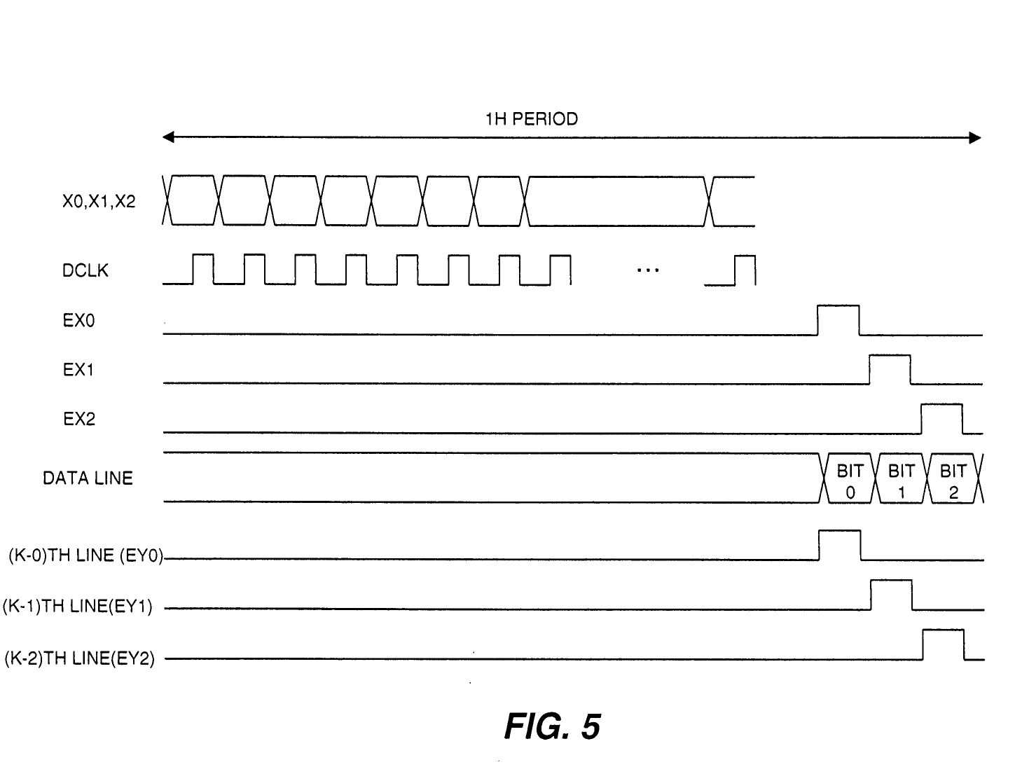

FIG. 4 shows an overall structure of a single-color active matrix organic EL panel of n rows and m columns, and FIG. 5 shows a driving timing chart of the active matrix organic EL panel. In a full-color display, similar structures are added to FIG. 4 for each color.

3-bit data are input to inputs X0 (bit 0), X1 (bit 1), and X2 (bit 2) of a data driver 11. When a dot clock DCLK (not shown in FIG. 4) is input to the data driver 11, data of one line are sequentially read to a shift register 13 storing data of each bit.

The 3-bit data of one line read into the shift register 13 are reflected in the data line 7 by a multiplexer 14 which controls an output of the read 3-bit data and enable lines EX0, EX1, and EX2. When the reading of the data of one line is completed, bit 0 is output to the data line 7 if the enable line EX0 is selected, bit 1 is output to the data line 7 if the enable line EX1 is selected, and bit 2 is output to the data line 7 if the enable line EX2 is selected.

At the same time, selection data (in the example configuration, High) are input to an input Y of a gate driver 12, and are subsequently read into a shift register 15. The shift register 15 sequentially transfers the selection data with a vertical transfer clock. Normally, of the shift register 15 of n lines, selection data (High) are stored only in the register of one line and this line is selected. When an enable line EY0 is selected on a kth line storing the selection data of the shift register 15, the divided pixel 10-0 of the kth line is selected and data of bit 0 supplied to the data line 7 are written to the divided pixel 10-0 of the kth line. Similarly, when an enable line EY1 is selected, data of bit 1 are written to the divided pixel 10-1 of the kth line, and, when an enable line EY2 is selected, data of bit 2 are written to the divided pixel 10-2 of the kth line. Because power supply voltages V0, V1, and V2 are supplied to the power supply lines 8-0, 8-1, and 8-2, respectively, a light emission intensity corresponding to the bit data of the pixel is obtained by the three divided pixels 10-0, 10-1, and 10-2.

By repeating these operations from the first line to the nth line, video data are written to all pixels and light emission from all of the pixels is controlled.

In this manner, by dividing a pixel into a plurality of pixels indicating a light emission intensity corresponding to the weight of the bit data, a multiple grayscale can be achieved. It is no longer necessary to achieve the multiple grayscale using sub-frames, and, thus, the frame memory is not necessary. By increasing the number of divided pixels to 6, 8, etc., it is possible to achieve multiple grayscale of 6 bits, 8 bits, etc.

Because the structure shown in FIG. 4 can be constructed from digital circuits, the data driver 11 and the gate driver 12 can be formed on a same glass substrate by using a high-performance transistor such as low temperature polysilicon, and, thus, cost can be further reduced.

The circuit of the divided pixel does not need to be the structure shown in FIGS. 1A and 1B having a static memory. Alternatively, it is also possible to employ a pixel circuit in which the second organic EL element 3 and the second driving transistor 4 are omitted and a storage capacitor is introduced between the gate terminal of the first driving transistor 2 and the power supply line 8. In this case, a refresh operation to periodically rewrite the video data at a predetermined period is necessary.

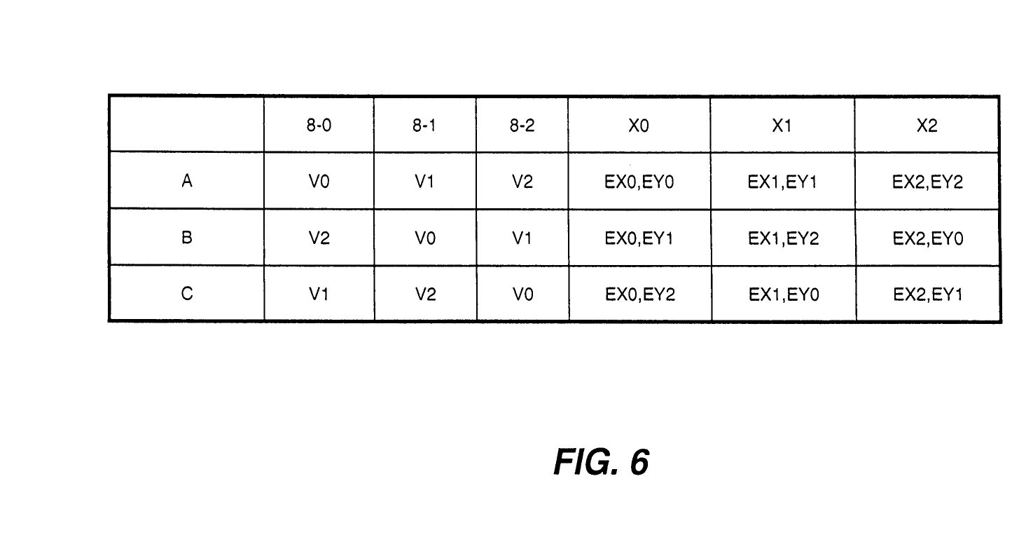

In order to make degradation of organic EL elements of the divided pixels uniform, the voltages V0, V1, and V2 to be supplied to the power supply lines 8-0, 8-1, and 8-2 may be switched at a suitable period. In other words, as shown in FIG. 6, a combination A of the voltage V0 to the power supply line 8-0, the voltage V1 to the power supply line 8-1, and the voltage V2 to the power supply line 8-2; a combination B of the voltage V2 to the power supply line 8-0, the voltage V0 to the power supply line 8-1, and the voltage V1 to the power supply line 8-2; and a combination C of the voltage V1 to the power supply line V1, the voltage V2 to the power supply line V2, and the voltage V0 to the power supply line 8-2 can be alternately switched at a certain timing, and the enable lines may be selected corresponding to the switched combination. In this manner, it is possible to write bit data to the divided pixels indicating light emission intensities corresponding to the bit data without a contradiction.

Specifically, when the combination is switched to combination B, the data of bit 0 are written to the divided pixel 10-1 having a power supply voltage of V0 supplied to the power supply line 8-1 by selection of EX0 and EY1, the data of bit 1 are written to the divided pixel 10-2 having a power supply voltage of V1 supplied to the power supply line 8-2 by the selection of EX1 and EY2, and the data of bit 2 are written to the divided pixel 10-0 having a power supply voltage of V2 supplied to the power supply line 8-0 by the selection of EX2 and EY0.

Similarly, when the combination is switched to combination C, the data of bit 0 are written to the divided pixel 10-2 having a power supply voltage of V0 supplied to the power supply line 8-2 by selection of EX0 and EY2, the data of bit 1 are written to the divided pixel 10-0 having a power supply voltage of V1 supplied to the power supply line 8-0 by selection of EX1 and EY0, and the data of bit 2 are written to the divided pixel 10-1 having a power supply voltage of V2 supplied to the power supply line 8-1 by selection of EX2 and EY1.

In this manner, by switching and supplying the power supply voltages V0, V1, and V2 to the power supply lines 8-0, 8-1, and 8-2, to write bit data to the corresponding pixels, the voltages applied to the divided pixels can be made uniform and the degradation of the organic EL element can be averaged.

Such a structure can be achieved by providing a switch which can be switched according to a signal indicating the selection of the combinations A, B, and C and switching so as to select which of the voltages V0, V1, and V2 is to be supplied to which of the power supply lines 8-0, 8-1, and 8-2.

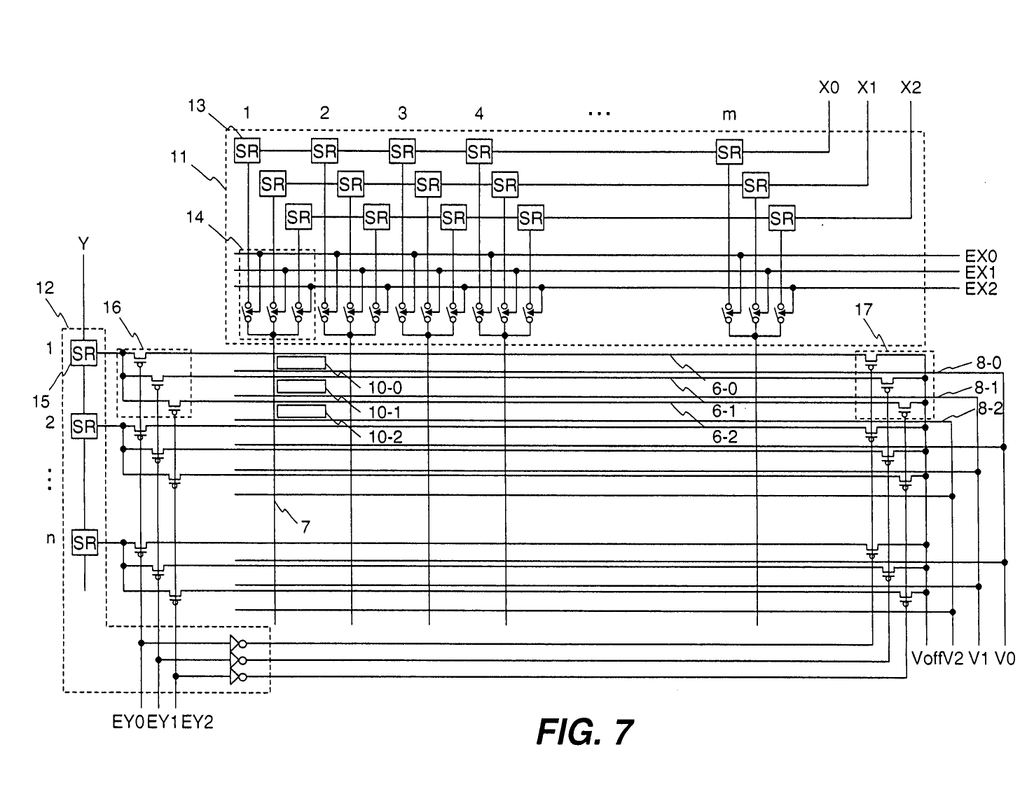

As shown in FIG. 7, it is preferable to employ a configuration in which the data driver 11 and the gate driver 12 are realized as a driver IC and other pixel circuits, and a selector 16 which selects and outputs an output of the gate driver 12 to the gate line 6, and a selector 17 which selects and outputs a voltage Voff for setting the gate transistor 5 not selected to the gate line 6 are formed by P-type transistors. When the organic EL panel is constructed with only P-type transistors in this manner, the cost can be further reduced, and a higher resolution which requires a higher speed operation and a larger size which requires a higher driving power can be easily realized.

An operation in the structure of FIG. 7 will now be described. When data are to be written to the divided pixel 10-0, only EY0 is set at Low (EY1 and EY2 are maintained at High). With this process, supply of non-selection voltage Voff to the gate lines 6-0 of the divided pixels 10-0 of all lines is cut and the gate lines 6-0 are connected to the output of the gate driver 12. The output of the gate driver 12 outputs a selection voltage Von only for one line and the non-selection signal Voff is output for the other lines. Because of this, the selection voltage Von is supplied only to the gate line 6-0 to be selected, and non-selection voltage Voff is supplied to all other gate lines 6-0. Thus, the data are written only to the selected line.

By repeating a similar operation for EY1 and EY2, a writing operation similar to that shown in FIG. 4 and degradation averaging process among the organic EL elements by switching of the power supply voltages V0-V2 can be realized using only P-type transistors, which are less expensive.

The invention has been described in detail with particular reference to certain preferred embodiments thereof, but it will be understood that variations and modifications can be effected within the spirit and scope of the invention.

### PARTS LIST

1 first organic EL element
2 first driving transistor
3 second organic EL element
4 second driving transistor
5 gate transistor
6 gate line
6-0 gate line
6-1 gate line
6-2 gate line
7 data line
8 power supply line
8-0 power supply line
8-1 power supply line
8-2 power supply line
9 cathode electrode
10-0 divided pixel
10-1 divided pixel
10-2 divided pixel
11 data driver
12 gate driver
13 shift register
14 multiplexer
15 shift register
16 selector
17 selector

1. An active matrix display device, wherein:
each pixel comprises a plurality of selectable divided pixels, wherein each divided pixel has a 1-bit static data storage element and emits light based on supplied data; and
the plurality of divided pixels each produces a weighted amount of light so that the selected divided pixels will cause a predetermined amount of light to be produced.

2. The active matrix display device of claim 1 wherein each of the divided pixels includes:
(i) a first organic EL element coupled to a first drive transistor; and
(ii) a second organic EL element coupled to a second drive transistor, the first and second drive transistors being connected to provide the 1-bit static data storage element;

3. The active matrix display device according to claim 1, wherein:
the amounts of light emission of the divided pixels are weighted by weighting power supply voltages to be supplied to the divided pixels.

4. The active matrix display device according to claim 3, wherein the power supply voltage to be supplied to the divided pixel can be switched.
